(19) United States
(12) Patent Application Publication
(10) Pub. No.: US 2017/0052232 A1
(43) Pub. Date: Feb. 23, 2017

(54) MAGNETIC SENSOR DEVICE

(71) Applicant: TDK Corporation, Tokyo (JP)

(72) Inventors: Yoshimitsu WADA, Tokyo (JP); Kunihiro UEDA, Tokyo (JP)

(21) Appl. No.: 15/196,194

(22) Filed: Jun. 29, 2016

(30) Foreign Application Priority Data
Aug. 21, 2015 (JP) 2015-163369

(51) Int. Cl. G01R 33/09

(52) U.S. Cl. CPC G01R 33/091; G01R 33/093; G01R 33/098; G01D 5/12

(57) ABSTRACT

A magnetic sensor device that can prevent an increase in detection error even when stress is applied to a magnetic sensor chip due to heat generation or the like at the time of operation includes a magnetic sensor chip that has a nearly-square shape in a plan view, and a die pad having a mounting surface where the magnetic sensor chip is mounted. Opening portions are formed at positions where four corners of the magnetic sensor chip mounted on the mounting surface overlap, respectively. An area ratio of the opening portions to an area of the die pad is 20% or greater. Also, an area of the overlapped portions with the magnetic sensor chip and the opening portions is 40% or greater relative to the area of the opening portions in a plan view of the die pad.

### CROSS REFERENCE TO RELATED APPLICATION

The present application is based on and claims the benefit of priority of Japanese Patent Application No. 2015-163369, filed on Aug. 21, 2015, the disclosure of which is incorporated herein by reference.

### TECHNICAL FIELD

The present invention relates to a magnetic sensor device where a magnetic sensor chip is mounted on a die pad.

### BACKGROUND TECHNOLOGY

Conventionally, in a machine tool or the like, a position detecting device is used for detecting the position of a moving body due to rotational movement or linear movement. As such a position detecting device, a device that includes a medium where magnetic signals are recorded and a magnetic sensor device is known. Due to fluctuations in the direction of a magnetic field when the medium and the magnetic sensor device move relative to one another, the magnetic sensor device can output a signal indicating their relative positional relationship.

As the magnetic sensor device used in such a position detecting device, a known device has a magnetic sensor chip, which is a multilayer body having a free layer and a magnetization pinned layer, and which includes a magnetoresistive effect element (MR element) with a resistance that is changed in association with a change in a magnetization direction of the free layer according to an external magnetic field, a die pad having a mounting surface where the magnetic sensor chip is mounted, and a plurality of leads that are arranged around the die pad and that are electrically connected to a terminal of the magnetic sensor chip, and where these are resin-sealed by transfer molding and are packaged.

In such a magnetic sensor device, stress (thermal stress) may be applied to the magnetic sensor chip due to heat generation or the like at the time of operation. In particular, the stress is concentrated on at least one of four corners of the magnetic sensor chip having a nearly rectangular shape in a planar view. Because the thermal stress in a direction which deforms the magnetic sensor chip and the die pad where the chip is mounted is applied to the corner, the detection error of the magnetic sensor device becomes greater.

Conventionally, while this is a technology relating to a resin seal type semiconductor device, for the purpose of preventing the occurrence of cracks in encapsulation resin due to heating at the time of mounting, a semiconductor device is proposed where notches and through-holes are formed around the periphery of a die pad where a semiconductor chip(s) is mounted (see Patent Literature 1).

### PRIOR ART LITERATURE

Japanese Patent Application Laid-Open No. H11-150213

### SUMMARY OF THE INVENTION

### Problem to be Solved by the Invention

In Patent Literature 1 above, the notch(es) and the through-hole(s) are formed around the periphery of the die pad where a semiconductor chip (semiconductor element) is mounted. However, when a magnetic sensor chip is used instead of the semiconductor chip in Patent Literature 1 above, it is difficult to reduce the stress (thermal stress) applied to a magnetic sensor chip due to heat generation at the time of operation so as to enable reduction of detection errors in the magnetic sensor device depending upon the area ratio of the notches or through-holes to an area of the die pad.

The objective of the present invention is to provide a magnetic sensor device that can prevent an increase in detection error even when stress is applied to a magnetic sensor chip due to heat generation or the like at the time of operation.

### Means for Solving the Problem

In order to solve the problem above, the present invention provides a magnetic sensor device that includes a magnetic sensor chip that has a square shape in a plan view, and a die pad having a mounting surface where the magnetic sensor chip is mounted. In the die pad, opening portions are formed in positions where four corners of the magnetic sensor chip mounted on the mounting surface overlap, respectively. The area ratio of the opening portions to an area of the die pad is 20% or greater. Also, the area of the overlapping portions with the magnetic sensor chips and the opening portions is 40% or greater relative to the area of the opening portions, in a plan view of the die pad.

According to the invention above, the opening portions corresponding to four corners of the magnetic sensor chip are formed in the die pad where the magnetic sensor chip is mounted. Because the area of the opening portions is within a predetermined numerical value, even when stress is applied to the magnetic sensor chip due to heat generation or the like at the time of operation, an increase in detection error can be prevented.

In the invention above, it is preferable that the area ratio of the opening portions to the area of the die pad is 20% to 40%. According to such an invention, even when thermal stress is applied to the magnetic sensor chip, an increase in detection error can be prevented, and the area where the mounting surface of the die pad contacts the magnetic sensor chip can be sufficiently secured; thus, the magnetic sensor chip can be assuredly fixed to the mounting surface.

In the invention above, it is preferable that the opening portions are formed independently in the die pad by having them correspond to the four corners of the magnetic sensor chip, respectively, and to have a nearly-circular shape or a nearly-elliptical shape.

In the invention above, it is preferable that a bonding layer intervenes between the magnetic sensor chip and the die pad to fix them with each other, and that the bonding layer is nearly cross-shaped in a plan view (Invention 4).

In the invention above, encapsulation resin bodies to seal at least the magnetic sensor chip and the die pad as a unit can be further provided, and as the magnetic sensor chip, a magnetic sensor chip containing a TMR element or a GMR element can be used.

### Effect of the Invention

According to the present invention, a magnetic sensor device that can prevent an increase in detection error even when stress is applied to a magnetic sensor chip due to heat generation or the like at the time of operation can be provided.

### BRIEF DESCRIPTION OF DRAWINGS

FIG. 1A is a plan view showing a schematic configuration of a magnetic sensor device relating to one embodiment of the present invention, and FIG. 1B is a plan view showing a schematic configuration of a die pad in one embodiment of the present invention.

FIG. 2 is a cross-sectional view along line I-I in FIG. 1A showing a schematic configuration of a magnetic sensor device relating to one embodiment of the present invention.

FIG. 3A is a circuit diagram schematically showing a circuit configuration of a first Wheatstone bridge circuit of a magnetic sensor chip in one embodiment of the present invention.

FIG. 3B is a circuit diagram schematically showing a circuit configuration of a second Wheatstone bridge circuit of a magnetic sensor chip in one embodiment of the present invention.

FIG. 4 is a cross-sectional view showing a schematic configuration of an MR element as a magnetic detecting element in one embodiment of the present invention.

FIG. 5 is a plan view showing a schematic configuration of a lead frame in one embodiment of the present invention.

FIG. 6A is a cutaway end view schematically showing a part of the manufacturing process of the magnetic sensor device relating to one embodiment of the present invention.

FIG. 6B is a cutaway end view schematically showing a part of the manufacturing process of the magnetic sensor device relating to one embodiment of the present invention.

FIG. 7 is a graph showing test results with magnetic sensor devices in Examples and in a Comparative Example.

### EMBODIMENT FOR CARRYING OUT THE INVENTION

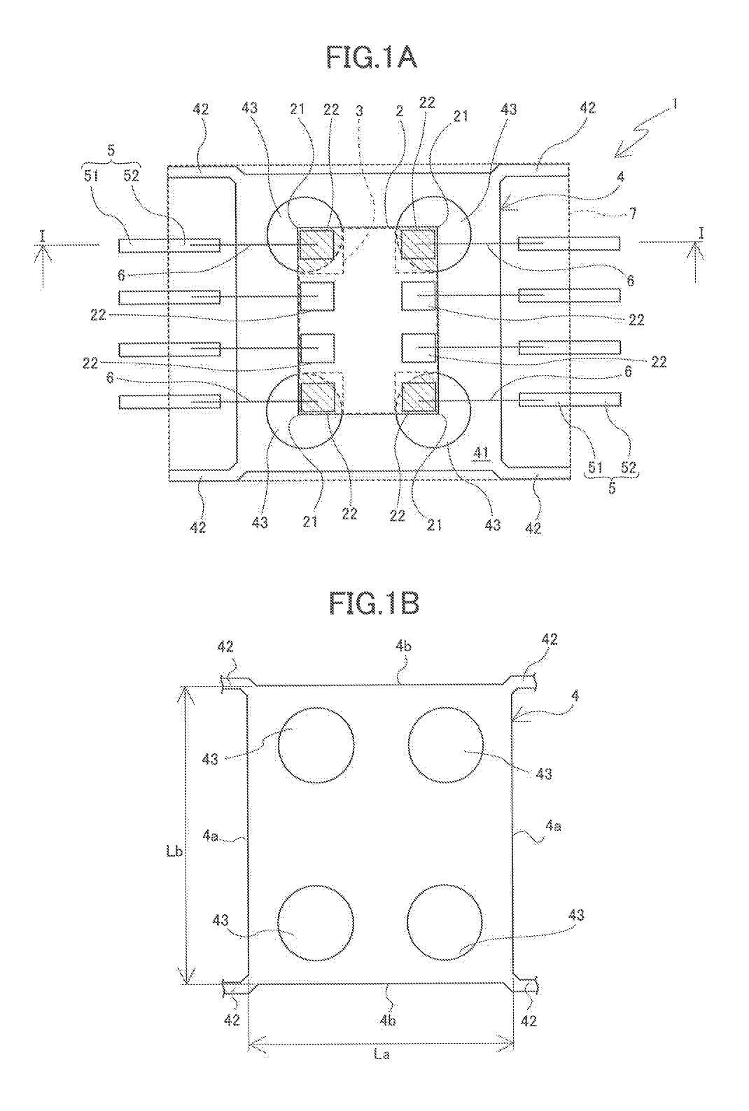

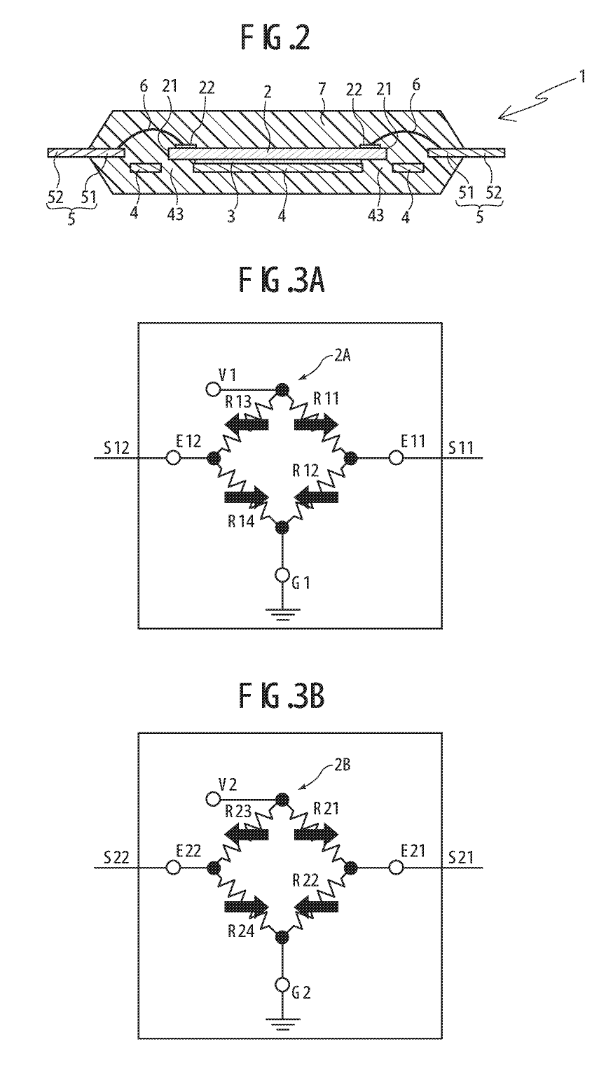

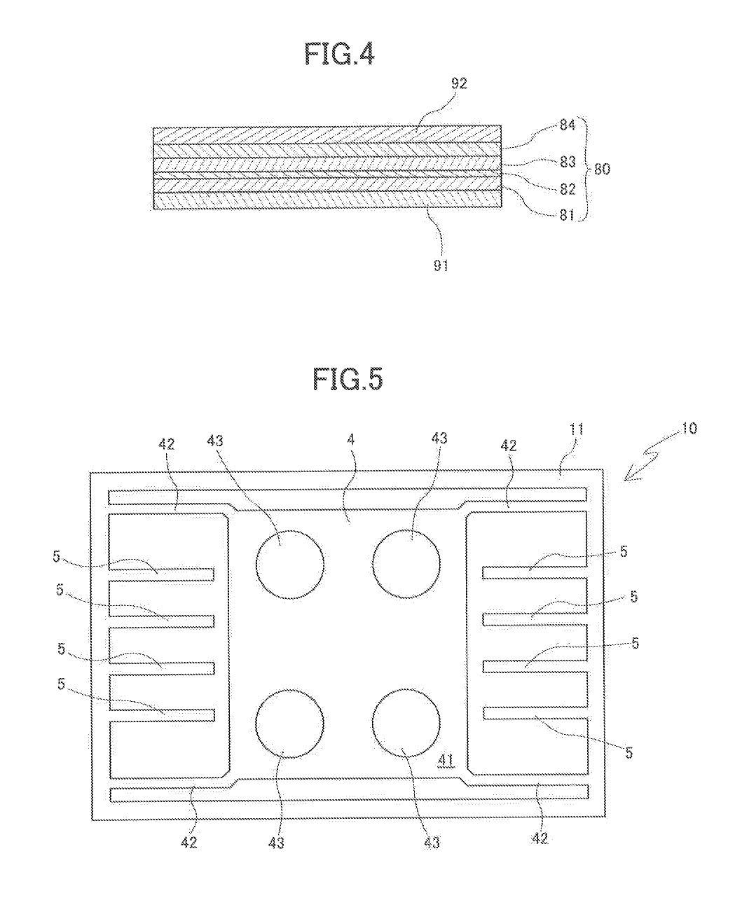

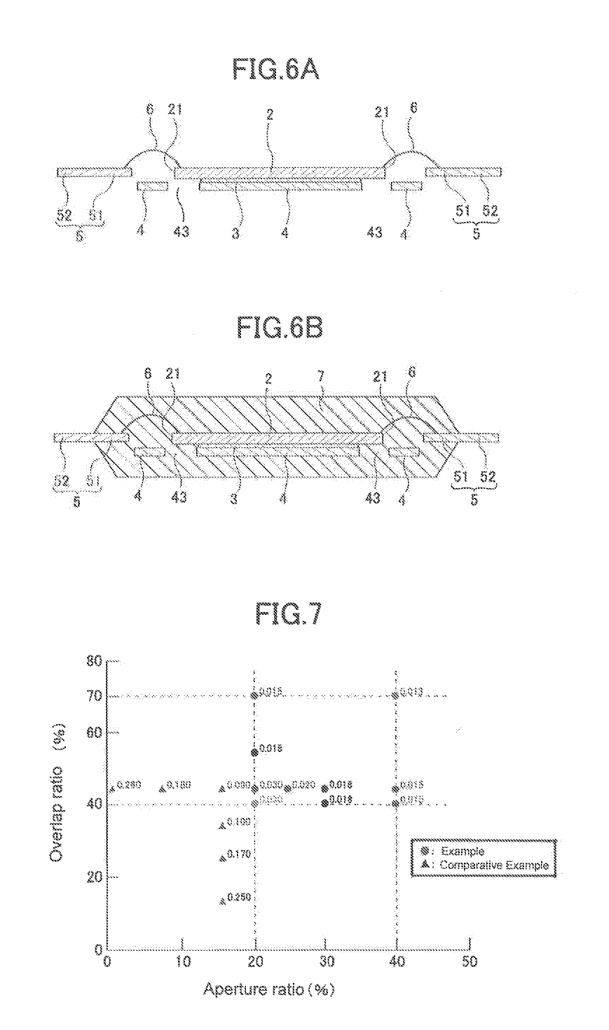

Embodiments of the present invention are explained in detail with reference to the drawings. FIG. 1A is a plan view showing a schematic configuration of a magnetic sensor device relating to one embodiment of the present invention, and FIG. 1B is a plan view showing a schematic configuration of a die pad in one embodiment of the present invention; FIG. 2 is a cross-sectional view along line I-I in FIG. 1A showing a schematic configuration of a magnetic sensor device relating to one embodiment of the present invention; FIG. 3A is a circuit diagram schematically showing a circuit configuration of a first Wheatstone bridge circuit_of a magnetic sensor chip in one embodiment of the present invention; FIG. 3B is a circuit diagram schematically showing a circuit configuration of a second Wheatstone bridge circuit of a magnetic sensor chip in one embodiment of the present invention; FIG. 4 is a cross-sectional view showing a schematic configuration of an MR element as a magnetic detecting element in one embodiment of the present invention; FIG. 5 is a plan view showing a schematic configuration of a lead frame in one embodiment of the present invention; and FIG. 6A and FIG. 6B are cutaway end view schematically showing a part of the manufacturing process of the magnetic sensor device relating to one embodiment of the present invention.

As shown in FIG. 1A, FIG. 1B and FIG. 2, a magnetic sensor device 1 relating to the present embodiment is used for detecting an angle of rotation or the like due to the relative movement of a rotating body or the like, and includes a magnetic sensor chip 2 that has a nearly square shape in a plan view, a die pad 4 where the magnetic sensor chip 2 is bonded and fixed via a bonding layer 3, a plurality of (eight in the present embodiment) leads 5 that are arranged around the die pad 4 and that include an inner lead 51 and an outer lead 52, respectively, wires 6 that electrically connect terminal pads 22 of the magnetic sensor chip 2 and the inner leads 51, respectively, and encapsulation resin bodies 7 that seal the magnetic sensor chip 2, the die pad 4, the inner leads 51 and the wires 6 as a unit.

The die pad 4 has a mounting surface 41 that has a nearly square shape in a plan view and where the magnetic sensor chip 2 is mounted, and suspension leads 42 that are continued to four corners of the die pad 4 and that support the die pad 4 to a frame part 11 of a lead frame 10 (see FIG. 5), described later.

Opening portions 43 where four corners 21 of the mounted magnetic sensor 2 overlap, respectively, are independently formed (without continuing with each other) on the mounting surface 41 of the die pad 4. In a plan view of the die pad 4 and the magnetic sensor chip 2 mounted on its mounting surface 41, the four corners 21 of the magnetic sensor chip 2 are physically included in four opening portions 43 formed on the mounting surface 41 of the die pad 4, respectively. Unless the corners 21 of the magnetic sensor chip 2 overlap with the opening portions 43, detection error is increased when stress is applied due to heat generation or the like at the time of operation. Furthermore, the shape of the opening portion 43 is not particularly limited; however, for example, a nearly circular shape, a nearly elliptical shape and the like are exemplified.

A total area of the four opening portions 43 formed in the die pad 4 is 20% or greater of the area of the die pad 4, and is preferably 20% to 40%. As it is clear from an example to be described later, if a ratio of the total area of the opening portions 43 to the area of the die pad 4 (an aperture ratio of the opening portions 43) is less than 20%, a detection error happens to be greater. Further, if the aperture ratio of the opening portions 43 exceeds 40%, bonding strength of the magnetic sensor chip 2 to the mounting surface 41 of the die pad 4 may be decreased, and a distance between the adjacent opening portions 43 in a direction along sides 4a and 4b of the die pad 4 having a nearly square shape in a plan view (longitudinal direction and lateral direction of an example shown in FIG. 1B) is decreased and the strength of the die pad 4 may be reduced. Furthermore, the area of the die pad 4 is expressed with the product (La×Lb) of the distance La between two sides 4a and 4a, which are opposed in one direction (lateral direction in the example shown in FIG. 1B) of the die pad 4 and are nearly in parallel, and another distance Lb between two sides 4b and 4b, which are opposed in the other direction (longitudinal direction in the example shown in FIG. 1B) that is orthogonal in the one direction above and are nearly in parallel.

In the top plan view of the die pad and the magnetic sensor chip 2 in FIG. 1A, a ratio (overlap ratio) of areas of portions where the four corners 21 of the magnetic sensor chip 2 overlap (shaded portions in FIG. 1A) the areas of the four opening portions 43 is 40% or greater, respectively. If the area ratio (overlap ratio) is less than 40%, a detection error in the magnetic sensor device 1 becomes greater. Furthermore, the upper limit value for the area ratio (overlap ratio) is not particularly limited as long as the corners 21 of the magnetic sensor chip 2 are positioned on the opening portions 43, respectively. For example, when the opening portions 43 are circular, if the area ratio exceeds 70%, the corners 21 of the nearly-square magnetic sensor chip 2 cannot be positioned on the opening portions 43, and the detection error is increased due to stress, which is concentrated at the corners 21 of the magnetic sensor chip 2 in association with heat generation at the time of operation.

The material configuring the die pad 4 is not particularly limited, but any known conductive materials can be used. As the conductive materials, for example, copper, stainless steel, aluminum, iron, ruthenium, silver and the like are exemplified.

The magnetic sensor chip 2 includes at least one magnetic detecting element. The magnetic sensor chip 2 may include a pair of magnetic detecting elements connected in series as at least one magnetic detecting element. In this case, the magnetic sensor chip 2 has two Wheatstone bridge circuits including a pair of first magnetic detecting elements connected in series and a pair of second magnetic detecting elements connected in series.

As shown in FIG. 3A, the first Wheatstone bridge circuit 2A in the magnetic sensor chip 2 includes a power port V1, a ground port G1, two output ports E11 and E12, a pair of first magnetic detecting elements R11 and R12 connected in series, and a pair of second magnetic detecting elements R13 and R14 connected in series. First ends of the magnetic detecting elements R11 and R13 are connected to the power source port V1, respectively. The second end of the magnetic detecting element R11 is connected to a first end of the magnetic detecting element R12 and the output port E11. The second end of the magnetic detecting element R13 is connected to a first end of the magnetic detecting element R14 and the output port E12. The second ends of the magnetic detecting elements R12 and R14 are connected to the ground port G1, respectively. A power source voltage with predetermined magnitude is applied to the power source port V1, and the ground port G1 is connected to ground.

As shown in FIG. 3B, the second Wheatstone bridge circuit 2B includes a power source port V2, a ground port G2, two output ports E21 and E22, a pair of first magnetic detecting elements R21 and R22 connected in series, and a pair of second magnetic detecting elements R23 and R24 connected in series. First ends of the magnetic detecting elements R21 and R23 are connected to the power port V2, respectively. The second end of the magnetic detecting element R21 is connected to a first end of the magnetic detecting element R22 and the output port E21. The second end of the magnetic detecting element R23 is connected to a first end of the magnetic detecting element R24 and the output port E22. The second ends of the magnetic detecting elements R22 and R24 are connected to the ground port G2, respectively. A power source voltage with a predetermined magnitude is applied to the power source port V2, and the ground port G2 is connected to ground.

In the present embodiment, MR elements, such as a TMR element or a GMR element, can be used as the magnetic detecting elements R11 to R14 and R21 to R24 included in the first and second Wheatstone bridge circuits 2A and 2B, respectively, and the TMR element is particularly preferable. The TMR element and the GMR element have a magnetization pinned layer where its magnetization direction is pinned, a free layer where its magnetization direction varies according to a direction of a magnetic field to be applied, and a nonmagnetic layer arranged between the magnetization pinned layer and the free layer.

Specifically, as shown in FIG. 4, the MR element has a plurality of lower-side electrodes 91, a plurality of MR films 80 and a plurality of upper-side electrodes 42. The plurality of lower-side electrodes 91 are provided on a substrate (not shown). Each lower-side electrode 91 has a long and narrow shape. A crevice is formed between two lower-side electrodes 91 that are adjacent in the longitudinal direction of the lower-side electrode 91. The MR films 80 are provided in the vicinity of both ends in the longitudinal direction on the upper surface of the lower-side electrode 91, respectively. The MR film 80 includes a free layer 81, a nonmagnetic layer 82, a magnetization pinned layer 83 and an antiferromagnetic layer 84 laminated in respective order from the lower-side electrode 91 side. Furthermore, a cap layer (not shown) is provided between the lower-side electrode 91 and the free layer 81 to electrically connect them, and an under layer (not shown) is provided between the antiferromagnetic layer and the upper-side electrode 92. The antiferromagnetic layer 84 is made from an antiferromagnetic material and fulfills the role of pinning the magnetization direction of the magnetization pinned layer 83 by causing exchange coupling with the magnetization pinned layer 83. The plurality of upper-side electrodes 92 are provided on the plurality of MR films 80. Each upper-side electrode 92 has a long and narrow shape, and is arranged on two lower-side electrodes 91 that are adjacent in the longitudinal direction of the lower-side electrodes 91, and electrically connects the antiferromagnetic layers 84 of the two adjacent MR films 80. Furthermore, the MR film 80 may have a configuration in which the free layer 81, the nonmagnetic layer 82, the magnetization pinned layer 83 and the antiferromagnetic layer 84 are laminated in respective order from the side of the upper-side electrode 92.

In the TMR element, the nonmagnetic layer 82 is a tunnel barrier layer. In the GMR element, the nonmagnetic layer 82 is a nonmagnetic conductive layer. In the TMR element and the GMR element, resistance values vary according to the angle between the magnetization direction of the free layer 81 and that of the magnetization pinned layer 83, and when the angle is 0° (the magnetization directions are parallel to each other), the resistance value is minimized, and when it is 180° (the magnetization directions are in antiparallel with each other), the resistance value is maximized.

In FIG. 3A and FIG. 3B, the magnetization directions of the magnetization pinned layer 83 in the magnetic detecting elements R11 to R14 and R21 to R24 are indicated by solid arrows, respectively. In the magnetic sensor chip 2, the magnetization directions of the magnetization pinned layers 83 in the magnetic detecting elements R11, R14, R21 and R24 and those of the magnetization pinned layers 83 in the magnetic detecting elements R12, R13, R22 and R23 are antiparallel to each other. In the magnetic sensor chip 2, signals S11 and S12 of sine waves indicating an intensity of a magnetic field are output from the output ports E11 and E12 according to changes in the magnetization direction of the free layer 81 in association with the change of an external magnetic field, and signals S21 and S22 of cosine waves indicating an intensity of a magnetic field are output from the output ports E21 and E22.

In the present embodiment, the magnetic sensor chip 2 is bonded and fixed on the mounting surface 41 of the die pad 4 via the bonding layer 3. As the material composed of the bonding layer 3, for example, a conductive paste, an insulating paste, a die attached film (DAF) and the like can be used.

The bonding layer 3 that bonds and fixes the magnetic sensor chip 2 onto the mounting layer 41 of the die pad 3 is nearly cross-shaped in a plan view. In the present embodiment, in order to prevent an increase in detection error due to thermal stress to be applied to the magnetic sensor chip 2, the four opening portions 43 are formed on the mounting surface 41 of the die pad 4. Consequently, while a leakage of a material configuring the bonding layer 3 from the opening portions 43 is prevented by shaping the bonding layer 3 intervening between the magnetic sensor chip 2 and the mounting surface 41 of the die pad 4 to be nearly cross-shaped in a plan view, the magnetic sensor chip 2 can be securely bonded and fixed to the mounting surface 41 of the die pad 4.

The wires 6 electrically connect the terminal pads 22 of the magnetic sensor chip 2 and the inner leads 51, and a bonding wire is used in the present embodiment. Leads 5 are an electrode used for extracting a signal, which is produced at the magnetic sensor chip 2, to an outside of the magnetic sensor device 1, and include the inner leads 51 that are electrically connected to the terminal pads 22 of the magnetic sensor chip 2 via the wires 6 and outer leads 52 that function as a member for mounting the magnetic sensor device 1, respectively. The inner leads 51 are portions that are sealed within the encapsulation resin bodies 7 out of the leads 5, and the outer leads 52 are portions that are exposed to the outside of the encapsulation resin bodies 7.

As a material configuring the leads 5, known conductive materials, which are the same materials as those for the die pad 4, (such as copper, stainless, aluminum, iron, ruthenium or silver) and the like can be used.

In the present embodiment, the leads 5 (inner lead 51 and outer lead 52) are located in a plane including a substantially center position in the thickness direction of the magnetic sensor chip 2 that is mounted (bonded and fixed) onto the mounting surface 41 of the die pad 4, and are positioned on a plane that is parallel to the mounting surface 41 (see FIG. 2), respectively, but are not limited to such a mode, and the leads 5 (inner lead 51 and outer lead 52) can be positioned on the same plane as the die pad 4. Because the leads 5 (inner lead 51 and outer lead 52) are positioned on the plane, when the outer leads 52 are positioned in substantially the center in the thickness direction of the magnetic sensor device 1, thickness of the encapsulation resin bodies 7 (resin material) positioned one above the other in the thickness direction of the magnetic sensor chip 2 can be nearly the same; thus, the detection error by the magnetic sensor device 1 can be further reduced. Furthermore, even when the leads 5 and the die pad 4 are positioned on the same plane, detection error at the magnetic sensor 1 can be further reduced by nearly equalizing the thickness of the encapsulation resin bodies 7 (resin material) positioned one above the other in the thickness direction of the magnetic sensor chip 2.

In the present embodiment, the resin material configuring the encapsulation resin bodies 7 should not be particularly limited, but the resin material that is used for a resin seal type semiconductor device and the like in general can be used.

In the magnetic sensor device 1 having the configuration above, stress is applied due to heat generation at the time of operation, and the stress in the direction that deforms the four corners 21 of the magnetic sensor chip 2 toward the die pad 4 side is concentrated. At this time, unless the opening portions 43 are formed in the die pad 4, because force, which is in a direction opposite to the direction that the stress acts (a direction toward the die pad 4 from the magnetic sensor chip 2), acts on the corners 21 of the magnetic sensor chip 2 from the die pad 4 side, when the thermal stress that is concentrated to the corners 21 becomes weakened or the like, the corners 21 are deformed in a direction away from the die pad 4. However, in the present embodiment, because the corners 21 where the thermal stress is concentrated are positioned on the opening portions 43 on the mounting surface 41 of the die pad 4, the opening portions 43 can function as a buffer of the thermal stress, thereby suppressing deformation of the magnetic sensor chip 2. Therefore, according to the magnetic sensor device 1 relating to the present embodiment, even if the thermal stress due to the heat generation at the time of operation is applied, an increase of the detection error can be prevented.

The magnetic sensor device 1 can be manufactured, for example, as mentioned below.

First, a lead frame 10 (see FIG. 5) is prepared that includes a frame part 11, the die pad 4 positioned within the frame part 11, a suspension lead 42 continuing the die pad 4 and the frame part 11, and a plurality of leads 5 that are continued to the frame part 11 and arranged around the die pad 4. Furthermore, the present exemplary embodiment includes the lead frame 10 having one die pad 4, but the lead frame 10 is not limited as such, and a so-called multi-surface frame having a plurality of die pads 4 is also acceptable.

A material configuring the bonding layer 3 is then applied onto a mounting surface 41 of the die pad 4 of the lead frame 10 to be nearly cross-shaped, the magnetic sensor chip 2 is fixed and bonded by the bonding layer 3, and the terminal pad 22 of the magnetic sensor 2 and the inner lead 51 are electrically connected by the wire 6 made of, for example, gold (see FIG. 6A). When fixing and bonding the magnetic sensor chip 2 to the die pad 4, the corners 21 of the magnetic sensor chip 2 are all permitted to be positioned on the opening portions 43 formed in the die pad 4.

Next, the lead frame 10 is accommodated within a mold, and the magnetic sensor chip 2, the die pad 4, the inner lead 51, the suspension lead 42 and the wire 6 are sealed with the encapsulation resin bodies 7 so as to expose the outer leads 52 to the outside (see FIG. 6B).

After that, the lead frame 10 sealed with the encapsulation resin bodies 7 is extracted from the mold, and the lead 5 and the suspension lead 42 are cut off so as to expose the outer leads 52 to the outside. Thus, the magnetic sensor device 1 relating to the present embodiment is manufactured.

The embodiment explained above was described to facilitate an understanding of the present invention, and is not described to limit the present invention. Therefore, each element disclosed in the embodiment is a concept including all changes of designs and equivalents belonging to the technical scope of the present invention.

### EXAMPLES

The present invention is explained in further detail hereafter with reference to examples and the like, but the present invention is not limited to the examples below.

### Example 1

The magnetic sensor device 1 having the configuration shown in FIG. 1A and FIG. 2 was prepared. In such magnetic sensor device 1, a diameter of the four circular opening portion 43 was adjusted to 0.46 mm, an area of the die pad 4 was adjusted to 1.69 mm² and an overlap ratio (an area ratio of portions where the corners 21 of the magnetic sensor chip 2 overlap (shaded portions indicated in FIG. 1A) to the area of the opening parts 43) was set at 45%. In a device to detect an angle of rotation using the magnetic sensor device 1 of Example 1, the detection error (deg) of an angle of rotation in the magnetic sensor device 1 was obtained. The results are shown in Table 1 and FIG. 7.

### Example 2

The magnetic sensor device 1 having a similar configuration to that of Example 1 except that the diameter of the four opening portions 43 was adjusted to 0.40 mm, and a detection error (deg) of the angle of rotation was obtained. The results are shown in Table 1 and FIG. 7.

### Example 3

The magnetic sensor device 1 having a similar configuration to that of Example 1 except that the diameter of the four opening portions 43 was adjusted to 0.36 mm, and a detection error (deg) of the angle of rotation was obtained. The results are shown in Table 1 and FIG. 7.

### Example 4

The magnetic sensor device 1 having a similar configuration to Example 1 except that the diameter of the four opening portions 43 was adjusted to 0.33 mm, and the detection error (deg) of the angle of rotation was obtained. The results are shown in Table 1 and FIG. 7.

### Example 5

The magnetic sensor device 1 having a similar configuration to Example 4 except that the overlap ratio was set at 40%, and the detection error (deg) of the angle of rotation was obtained. The results are shown in Table 1 and FIG. 7.

### Example 6

The magnetic sensor device 1 having a similar configuration as that of Example 4 except that the overlap ratio was set at 55%, and the detection error (deg) of the angle of rotation was obtained. The results are shown in Table 1 and FIG. 7.

### Example 7

The magnetic sensor device 1 having a similar configuration to Example 4 except that the overlap ratio was set at 70%, and the detection error (deg) of the angle of rotation was obtained. The results are shown in Table 1 and FIG. 7.

### Example 8

The magnetic sensor device 1 having a similar configuration to that of Example 2 except that the overlap ratio was set at 40%, and the detection error (deg) of the angle of rotation was obtained. The results are shown in Table 1 and FIG. 7.

### Example 9

The magnetic sensor device 1 having a similar configuration to that of Example 1 except that the overlap ratio was set at 40%, and the detection error (deg) of the angle of rotation was obtained. The results are shown in Table 1 and FIG. 7.

### Example 10

The magnetic sensor device 1 having a similar configuration as that of Example 1 except that the overlap ratio was set at 70%, and the detection error (deg) of the angle of rotation was obtained. The results are shown in Table 1 and FIG. 7.

### Comparative Example 1

The magnetic sensor device 1 having a similar configuration to Example 1 except that the diameter of the four opening portions 43 was adjusted to 0.30 mm, and the detection error (deg) of the angle of rotation was obtained. The results are shown in Table 1 and FIG. 7.

### Comparative Example 2

The magnetic sensor device 1 having a similar configuration to Example 1 except that the diameter of the four opening portions 43 was adjusted to 0.20 mm, and a detection error (deg) of the angle of rotation was obtained. The results are shown in Table 1 and FIG. 7.

### Comparative Example 3

The magnetic sensor device 1 having a similar configuration to Example 1 except that the diameter of the four opening portions 43 was adjusted to 0.10 mm, and the detection error (deg) of the angle of rotation was obtained. The results are shown in Table 1 and FIG. 7.

### Comparative Example 4

The magnetic sensor device 1 having a similar configuration to Comparative Example 1 except that the overlap ratio was set at 35%, and a detection error (deg) of the angle of rotation was obtained. The results are shown in Table 1 and FIG. 7.

### Comparative Example 5

The magnetic sensor device 1 having a similar configuration to Comparative Example 1 except that the overlap ratio was set at 25%, and a detection error (deg) of the angle of rotation was obtained. The results are shown in Table 1 and FIG. 7.

### Comparative Example 6

The magnetic sensor device 1 having a similar configuration to Comparative Example 1 except that the overlap ratio was set at 13%, and the detection error (deg) of the angle of rotation was obtained. The results are shown in Table 1 and FIG. 7.

TABLE 1

| | | Total | | | |
|---|---|---|---|---|---|
| | Diameter of | area of | | | |
| | opening | opening | | | |
| | portion | portion | Aperture | Overlap | Detection |
| | (mm) | (mm²) | ratio (%) | ratio (%) | error (deg) |
| Example 1 | 0.46 | 0.665 | 39.33 | 45 | 0.015 |
| Example 2 | 0.40 | 0.503 | 29.74 | 45 | 0.018 |
| Example 3 | 0.36 | 0.407 | 24.09 | 45 | 0.020 |
| Example 4 | 0.33 | 0.342 | 20.24 | 45 | 0.030 |
| Example 5 | 0.33 | 0.342 | 20.24 | 40 | 0.030 |
| Example 6 | 0.33 | 0.342 | 20.24 | 55 | 0.018 |
| Example 7 | 0.33 | 0.342 | 20.24 | 70 | 0.015 |
| Example 8 | 0.40 | 0.503 | 29.74 | 40 | 0.018 |
| Example 9 | 0.46 | 0.665 | 39.33 | 40 | 0.015 |
| Example 10 | 0.46 | 0.665 | 39.33 | 70 | 0.013 |
| Comparative | 0.30 | 0.283 | 16.73 | 45 | 0.090 |
| Example 1 | | | | | |
| Comparative | 0.20 | 0.126 | 7.44 | 45 | 0.180 |
| Example 2 | | | | | |
| Comparative | 0.10 | 0.031 | 1.86 | 45 | 0.260 |
| Example 3 | | | | | |
| Comparative | 0.30 | 0.283 | 16.73 | 35 | 0.100 |
| Example 4 | | | | | |
| Comparative | 0.30 | 0.283 | 16.73 | 25 | 0.170 |
| Example 5 | | | | | |
| Comparative | 0.30 | 0.283 | 16.73 | 13 | 0.250 |
| Example 6 | | | | | |

As is clear from results shown in Table 1 and FIG. 7, for the magnetic sensor device 1 where the magnetic sensor chip 2 is mounted on the mounting surface 41 of the die pad 4 with 20% or greater of an aperture ratio so as to overlap the corners 21 onto the opening portions 43 of the die pad 4, and so as to set the overlap ratio at 40% or greater, it was confirmed that detection error can be dramatically reduced.

### DESCRIPTION OF SYMBOLS

1 . . . magnetic sensor device
2 . . . magnetic sensor chip
21 . . . corner
3 . . . bonding layer
4 . . . die pad
41 . . . mounting surface
43 . . . opening portion
5 . . . lead
7 . . . encapsulation resin body

What is claimed is:

1. A magnetic sensor device, comprising:
a magnetic sensor chip that has a square shape in a plan view, and
a die pad including a mounting surface where the magnetic sensor chip is mounted, wherein
in the die pad, opening portions are formed at positions where four corners of the magnetic sensor chip mounted on the mounting surface overlap, respectively;
an area ratio of the opening portions to an area of the die pad is 20% or greater; and
an area of overlapped portions of the magnetic sensor chip and the opening portions is 40% or greater relative to the area of the opening portions, in a plan view of the die pad.

2. The magnetic sensor device according to claim 1, wherein
the area ratio of the opening portions to the area of the die pad is 20% to 40%.

3. The magnetic sensor device according to claim 1, wherein
the opening portions are formed independently in the die pad by corresponding to the four corners of the magnetic sensor chip, respectively, and have a nearly-circular shape or a nearly-elliptical shape.

4. The magnetic sensor device according to claim 1, wherein
a bonding layer to fix the magnetic sensor chip and the die pad with each other is located between the magnetic sensor chip and the die pad; and
the bonding layer is nearly cross-shaped in a plan view.

5. The magnetic sensor device according to claim 1, further comprising:
encapsulation resin bodies that seal at least the magnetic sensor chip and the die pad as a unit.

6. The magnetic sensor device according to claim 1, wherein
the magnetic sensor chip is a magnetic sensor chip containing a TMR element or a GMR element.
